(19) United States
(12) Patent Application Publication
(10) Pub. No.: US 2013/0071970 A1
(43) Pub. Date: Mar. 21, 2013

(54) MANUFACTURING METHOD OF SEMICONDUCTOR DEVICE

(71) Applicant: Yuji FUJIMOTO, Kanagawa (JP)

(72) Inventor: Yuji FUJIMOTO, Kanagawa (JP)

(73) Assignee: RENESAS ELECTRONICS CORPORATION, Kanagawa (JP)

(21) Appl. No.: 13/563,389

(22) Filed: Jul. 31, 2012

(30) Foreign Application Priority Data
Sep. 21, 2011 (JP) 2011-206573

(51) Int. Cl. H01L 21/78

(52) U.S. Cl. 438/113; 257/E21.599

(57) ABSTRACT

The present invention makes it possible to inhibit cutting burrs from forming in package dicing.

It is possible, in a package dicing step, to: inhibit cutting burrs from forming by cutting a part of a sealing body including leads with a soft resin blade as first step cutting; successively decrease the generation of a remaining uncut part because the progression of the abrasion of a blade main body is slow by cutting only a resin part that is a remaining uncut part with a hard electroformed blade as second step cutting; and resultantly improve the reliability of a semiconductor device.

### CROSS-REFERENCE TO RELATED APPLICATIONS

The disclosure of Japanese Patent Application No. 2011-206573 filed on Sep. 21, 2011 including the specification, drawings and abstract is incorporated herein by reference in its entirety.

The present invention relates to a manufacturing technology of a semiconductor device, in particular to a technology effective in applying it to package dicing.

### BACKGROUND

As a method for cutting a resin-sealed body in the assembly of a semiconductor device, a technology including a step of shaving the resin-sealed body from a radiator plate side and a step of shaving the resin-sealed body from a circuit board side and being used for cutting the resin-sealed body with blades having abrasive grain sizes different from each other in the steps is disclosed in Patent Literature 1 for example.

Further, a technology of forming a semiconductor device separated individually by cutting a lead terminal to the middle from the bottom face side with a blade and successively cutting a resin layer and a lead frame simultaneously from the opposite side with a blade in the assembly of the semiconductor device is disclosed in Patent Literature 2 for example.

Furthermore, a technology of cutting a wafer to the middle with a first dicing blade and successively cutting a remaining uncut part completely with an ultrathin second dicing blade in the dicing of the wafer is disclosed in Patent Literature 3 for example.

### PREVIOUS TECHNICAL LITERATURE

### Patent Literature

### Patent Literature 1

Japanese Unexamined Patent Publication No. 2010-103297

### Patent Literature 2

Japanese Unexamined Patent Publication No. H11-163007

### Patent Literature 3

Japanese Unexamined Patent Publication No. 2005-129830

### SUMMARY

In the assembly of a semiconductor device, in the case of the assembly of a semiconductor device by an MAP (Matrix Array Package) method of using a lead frame, a sealed body is formed by collectively sealing a plurality of device regions in a lead frame with a resin and successively package dicing (singulation) is carried out.

Consequently, in package dicing, the metal part of a lead and the resin part of a sealed body have to be cut simultaneously. That is, it means that a plurality of different materials (here, a metal and a resin) are cut simultaneously.

In general, as a cutting blade (cutter) used in a dicing machine, an electroformed blade, a metal blade, a resin blade, etc. are known and they are selectively used in accordance with the respective characteristics. For example, they are selectively used in accordance with characteristics such as an abrasion rate, a cutting sharpness, etc. of respective blades and the quality of a work material, etc. but, in package dicing as stated above, a member including the mixture of a metal and a resin has to be cut sharply in consideration of an abrasion rate unlike conventional wafer dicing and hence what blade is to be used for package dicing comes to be important.

In recent years, by the influence of downsizing or a higher number of pins in a semiconductor device, a pitch between leads in a semiconductor device tends to narrow (for example, narrow from 0.5 mm to 0.4 mm in pitch) and a problem here is that cutting burrs of a metal formed during package dicing cause short-circuit between leads.

In the cases of the three types of blades stated above, if a blade hardens (a hardness increases), the abrasion of the blade itself reduces and the apprehension that an uncut part remains also reduces, but on the other hand cutting burrs tend to be formed and short-circuit between leads and mounting failure are caused.

When a blade softens (a hardness reduces) in contrast, cutting burrs reduce but the abrasion of the blade itself accelerates and an uncut part tends to remain.

In this way, even merely in the case of the hardness of a blade, advantages and disadvantages coexist and the selection of a blade is very difficult in package dicing.

The present invention has been established in view of the above situation and an object thereof is to provide a technology that makes it possible to inhibit the occurrence of cutting burrs in package dicing.

Further, another object of the present invention is to provide a technology that makes it possible to improve the reliability of a semiconductor device.

The above and other objects and novel features of the present invention will appear from the descriptions and attached drawings in the present specification.

The representative outline of the invention disclosed in the present application is briefly explained below.

A method for manufacturing a semiconductor device according to a representative embodiment includes the steps of collectively sealing a plurality of semiconductor chips with a sealing body and successively, when the sealing body and plural leads are cut and singulated, retaining the top face of the sealing body, cutting a part of the sealing body and the plural leads from the bottom face side of the sealing body with a first blade, and inserting a second blade having a thickness thinner than the thickness of the first blade into a first groove formed in the cutting step and cutting a remaining uncut part of the sealing body, and the force of the first blade for retaining abrasive grains is lower than the force of the second blade for retaining abrasive grains.

Further, a method for manufacturing a semiconductor device according to another representative embodiment includes the steps of collectively sealing a plurality of semiconductor chips with a sealing body and successively, when the sealing body and plural leads are cut and singulated, retaining the top face of the sealing body, cutting a part of the sealing body and the plural leads from the bottom face side of the sealing body with a first blade, and inserting a second blade having a thickness thinner than the thickness of the first blade into a first groove formed in the cutting step and cutting a remaining uncut part of the sealing body, and the abrasion rate of the first blade is larger than the abrasive rate of the second blade.

The effects obtained by the representative invention in the invention disclosed in the present application are briefly explained below.

It is possible to inhibit cutting burrs from forming during package dicing.

Further, it is possible to improve the reliability of a semiconductor device.

The present invention is preferably used for the assembly of an electronic device to which package dicing is applied.

### BRIEF DESCRIPTION OF THE DRAWINGS

FIG. 1 is a perspective view showing an example of the structure of a semiconductor device in an embodiment according to the present invention.

FIG. 2 is a plan view showing an example of the structure of the semiconductor device shown in FIG. 1.

FIG. 3 is a rear view showing an example of the structure of the semiconductor device shown in FIG. 1.

FIG. 4 is a sectional view showing an example of the structure taken on line A-A in FIG. 3.

FIG. 5 is a sectional view showing an example of the structure taken on line B-B in FIG. 3.

FIG. 6 comprises plan views showing the steps up to wire bonding in the assembly sequence of the semiconductor device shown in FIG. 1.

FIG. 7 comprises sectional views showing the steps up to wire bonding in the assembly sequence shown in FIG. 6.

FIG. 8 comprises plan views and a perspective view showing the steps of resin sealing to assembly completion in the assembly sequence of the semiconductor device in FIG. 1.

FIG. 9 comprises sectional views showing the steps up to assembly completion in the assembly sequence shown in FIG. 8.

FIG. 10 comprises plan views showing the details of singulation cutting in the assembly sequence shown in FIG. 8.

FIG. 11 is a conceptual diagram showing a cutting burr generating mechanism in package dicing.

FIG. 12 is a conceptual diagram showing the cutting burr generating mechanism in FIG. 11.

FIG. 13 is a conceptual diagram showing the cutting burr generating mechanism in FIG. 11.

FIG. 14 comprises conceptual diagrams showing the state of a blade having no clogging in package dicing.

FIG. 15 comprises conceptual diagrams showing the state of a blade having clogging in package dicing.

FIG. 16 comprises conceptual diagrams showing examples of the manufacturing methods of respective blades used in an embodiment according to the present invention.

FIG. 17 is a conceptual diagram showing examples of the characteristics of respective blades used in an embodiment according to the present invention.

FIG. 18 is a conceptual diagram showing examples of the specifications and the cutting conditions of respective blades used in an embodiment according to the present invention.

FIG. 19 is a perspective view showing an example of the state of cutting with a first blade in a singulation cutting step according to an embodiment of the present invention.

FIG. 20 is a perspective view showing an example of the state of cutting with a second blade in a singulation cutting step according to an embodiment of the present invention.

FIG. 21 is a plan view showing an example of the structure after cut with the first blade in FIG. 19.

FIG. 22 is a plan view showing an example of the structure after cut with the second blade in FIG. 20.

FIG. 23 is a graph comparing the quantities of the generated cutting burrs measured in the cases of an electroformed blade and a resin blade.

FIG. 24 is a conceptual diagram showing cutting burrs in the measurement of FIG. 23.

FIG. 25 is a perspective view showing an example of cutting burrs formed in package dicing.

FIG. 26 is a partial sectional view showing an example of a remaining uncut part formed in package dicing.

### DETAILED DESCRIPTION

In the following embodiment, an explanation on the same part or a similar part is not repeated in principle except for a particularly necessary case.

Further, in the following embodiment, explanations are made in the manner of being divided into plural sections or embodiments for convenience when it is necessary but, unless otherwise specified, they are not unrelated to each other and one is related to another as a modified example, a detail, or a supplemental remark of a part or the whole thereof.

Furthermore, in the following embodiment, when the number of components (including the number of pieces, a value, a quantity, a range, etc.) or the like is mentioned, the number is not particularly limited to the specific number and may be more or less than the specific number unless otherwise specified or obviously limited to the specific number in principle.

In addition, in the following embodiment, it is needless to say that constituent components (including component steps) are not always essential unless otherwise specified or considered to be essential in principle.

Furthermore, in the following embodiment, it is needless to say that, when a phrase such as “composed of A”, “comprising A”, “having A”, or “including A” is used with regard to a constituent component or the like, it does not mean to exclude components other than A unless particularly specified only as the component. Similarly, in the following embodiment, when a shape, positional relationship, etc. of a constituent component or the like are mentioned, a shape or the like which is substantially close or similar to the shape is included unless otherwise specified or considered to be otherwise in principle. The same goes for a value or a range stated above.

An embodiment according to the present invention is hereunder explained in detail in reference to drawings. Here, in all the drawings for explaining the embodiment, members having an identical function are represented with an identical code and repetitive explanations are omitted.

### Embodiment

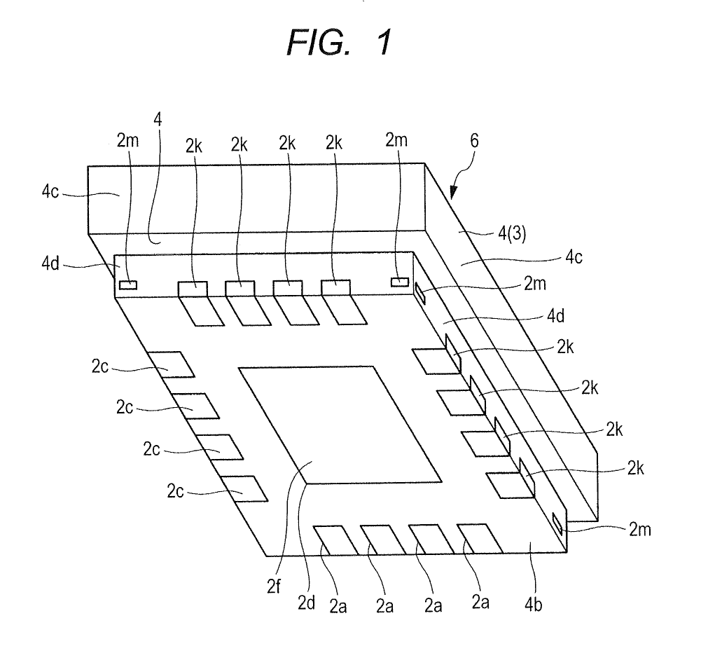

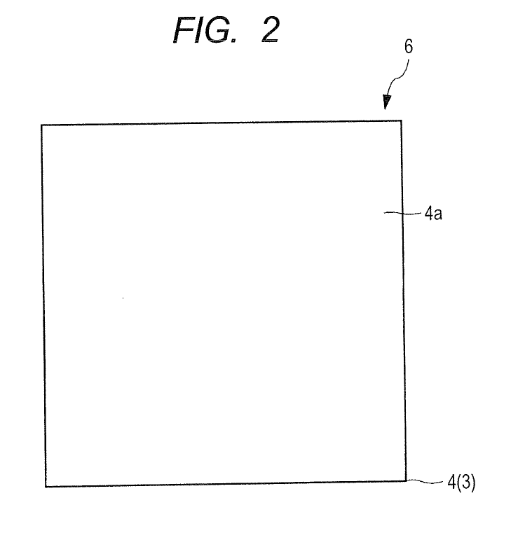

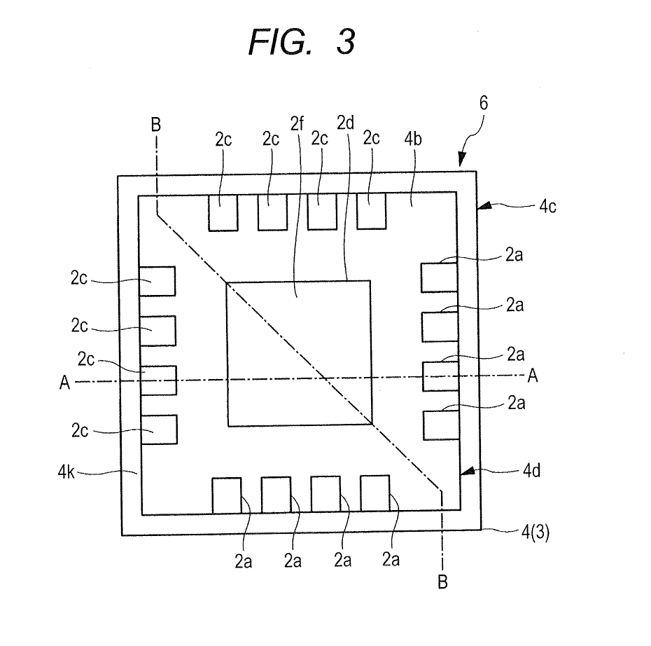

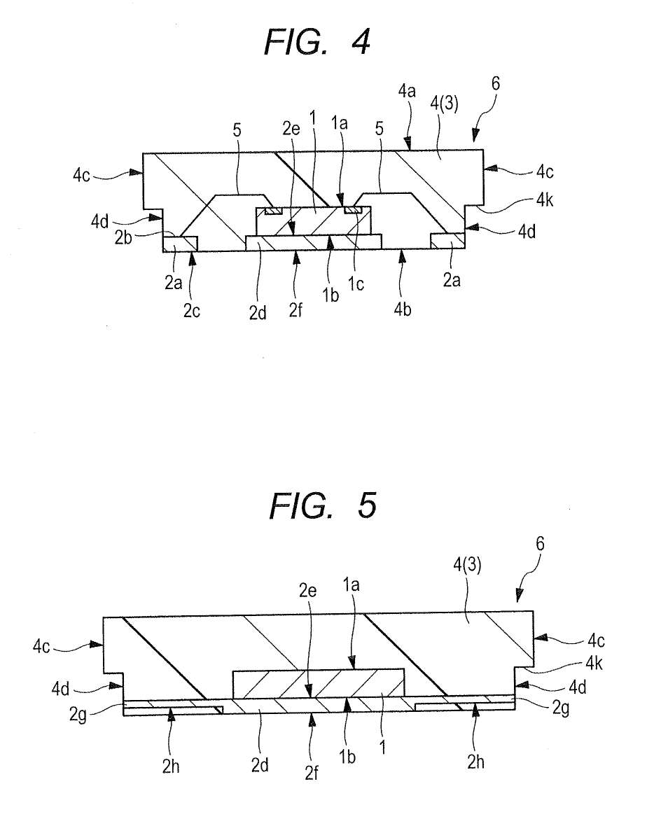

FIG. 1 is a perspective view showing an example of the structure of a semiconductor device in an embodiment according to the present invention, FIG. 2 is a plan view showing an example of the structure of the semiconductor device shown in FIG. 1, FIG. 3 is a rear view showing an example of the structure of the semiconductor device shown in FIG. 1, FIG. 4 is a sectional view showing an example of the structure taken on line A-A in FIG. 3, and FIG. 5 is a sectional view showing an example of the structure taken on line B-B in FIG. 3.

A semiconductor device according to the present embodiment shown in FIGS. 1 to 5 is a lead frame type semiconductor package formed by sealing a semiconductor chip 1 mounted over a top face 2e of a tabular die pad (chip mounting part, tab) 2d for mounting the semiconductor chip 1 with a sealing body 4 including a resin and electrically coupling the semiconductor chip 1 to leads 2a including a metal through metal wires 5.

Further, each of the plural leads 2a arranged around the semiconductor chip 1 is exposed as an external terminal at the periphery of a bottom face 4b of the sealing body 4. In the present embodiment, a QFN (Quad Flat Non-leaded Package) 6 is taken up and explained as an example of such a semiconductor device as mentioned above.

A QFN 6 is assembled by adopting an MAP method. That is, the QFN 6 is assembled by resin-sealing a plurality of semiconductor chips 1 collectively and then applying package dicing (blade dicing, singulation cutting).

As shown in FIG. 4, a semiconductor integrated circuit is incorporated into the interior of a semiconductor chip 1 incorporated into a QFN 6. The semiconductor chip 1 is arranged over and bonded (fixed, adhered) to a top face 2e of a die pad 2d through a die bond material such as silver paste, for example. In other words, a rear face 1b of the semiconductor chip 1 and the top face 2e of the die pad 2d are bonded to each other through the die bond material. Further, a plurality of electrode pads 1c electrically coupled to parts of the semiconductor integrated circuit are formed over the obverse surface 1a of the semiconductor chip 1. Each of the plural electrode pads 1c is electrically coupled to each of the plural leads 2a through each of a plurality of metal wires 5. Each of the plural leads 2a has a top face 2b and a bottom face 2c on the opposite side. The top face 2b is coupled to a metal wire 5 and the bottom face 2c is exposed at a periphery of the bottom face 4b of a sealing body 4 as shown in FIG. 3.

Here, with regard to the die pad 2d to which the semiconductor chip 1 is bonded too, a bottom face 2f on the opposite side of the top face 2e is exposed from the bottom face 4b of the sealing body 4. That means that the QFN 6 is an exposed die pad type (exposed tab type) semiconductor device.

As shown in FIG. 5 further, suspension leads 2g supporting the die pad 2d are arranged in the QFN 6. Here, the four suspension leads 2g support the corner parts of the die pad 2d. The thickness of the suspension leads 2g is reduced by half etching. That is, a bottom face 2h of each of the suspension leads 2g is a plane formed by half etching. Each of the four suspension leads 2g is shaved on the side of the bottom face 2h by half etching processing and the thickness thereof is about a half of the thickness of the die pad 2d. Consequently, the bottom face 2h of each of the suspension leads 2g is covered with the sealing body 4 and is not exposed from the bottom face 4b of the sealing body 4 as shown in FIGS. 3 and 5.

Further, a sealing body 4 in a QFN 6 according to the present embodiment has a bottom face 4b acting as a mounting plane for a substrate and the like, a planar top face 4a located on the other side, and moreover four side faces located between the top face 4a and the bottom face 4b as shown in FIGS. 2 and 4. Each of the four side faces has a first side face 4c and a second side face 4d located inside the first side face 4c. Each of the first side faces 4c includes only a resin 3 as shown in FIG. 1. Further, on each of the second side faces 4d, cut planes 2k of plural leads 2a and cut planes 2m of plural suspension leads 2g arranged at both the ends so as to interpose the cut planes 2k are exposed.

That is, each of the four side faces of the sealing body 4 forms a step-like shape. It includes a first side face 4c leading from the top face 4a of the sealing body 4 and a second side face 4d formed at a position receding from the first side face 4c toward the inside of the package and the second side face 4d leads to the bottom face 4b. On each of the second side faces 4d, cut planes 2k and 2m of the leads 2a and suspension leads 2g are exposed. Here, the first side faces 4c and the second side faces 4d also lead to second bottom faces 4k. A second bottom face 4k is a plane located between a top face 4a and a bottom face 4b.

Each of the four side faces is formed into a step-like shape as stated above and hence the bottom face 4b is smaller than the top face 4a. That is, the area of the bottom face 4b is smaller than the area of the top face 4b in a planer view.

Here, a semiconductor chip 1 incorporated into a QFN 6 includes silicon for example and a metal wire 5 is a gold (Au) wire, a copper (Cu) wire, or an aluminum (Al) wire for example. Further, a resin 3 used for forming a sealing body 4 is a thermosetting epoxy resin for example. Further, each lead 2a, each suspension lead 2g, and a die pad 2d includes an iron-nickel alloy, a copper alloy, or the like.

Assembly (manufacturing method) of a QFN 6 according to the present embodiment is explained hereunder.

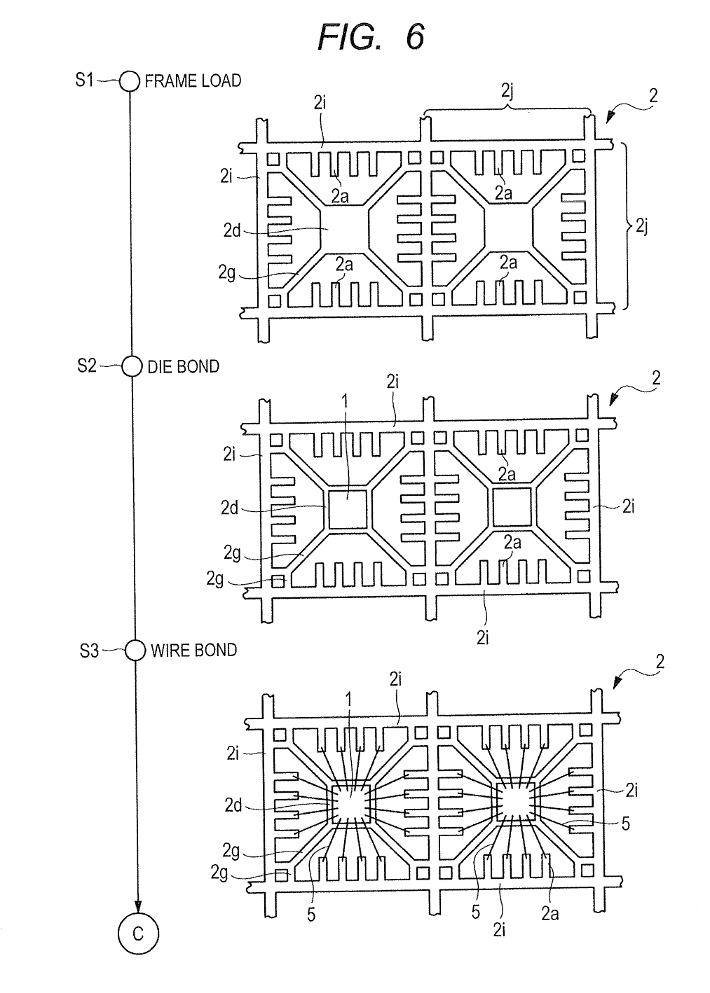

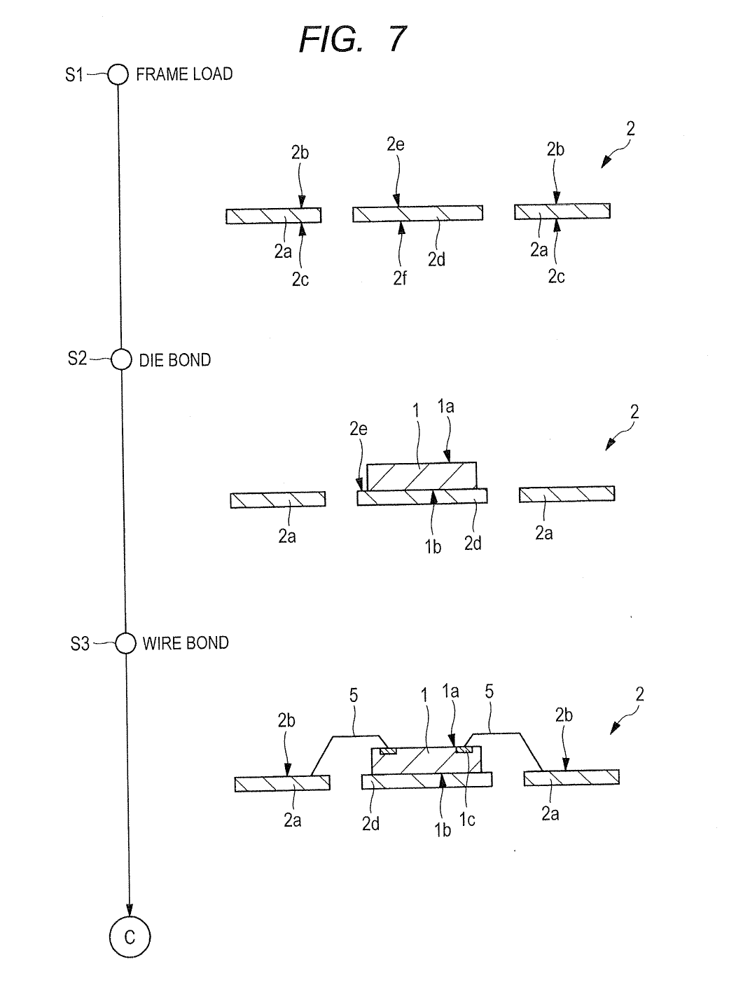

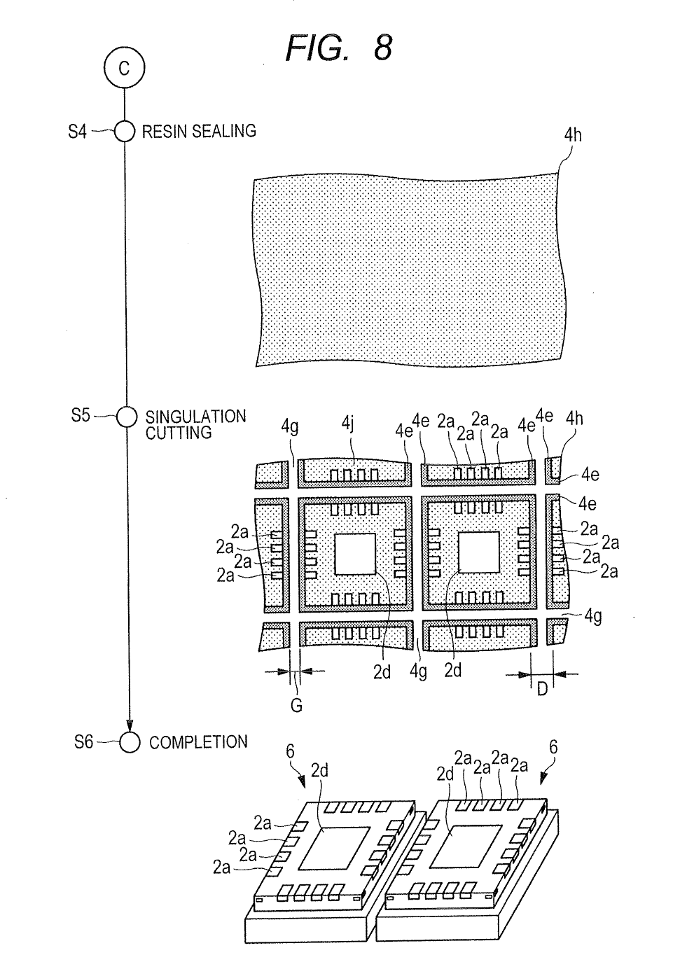

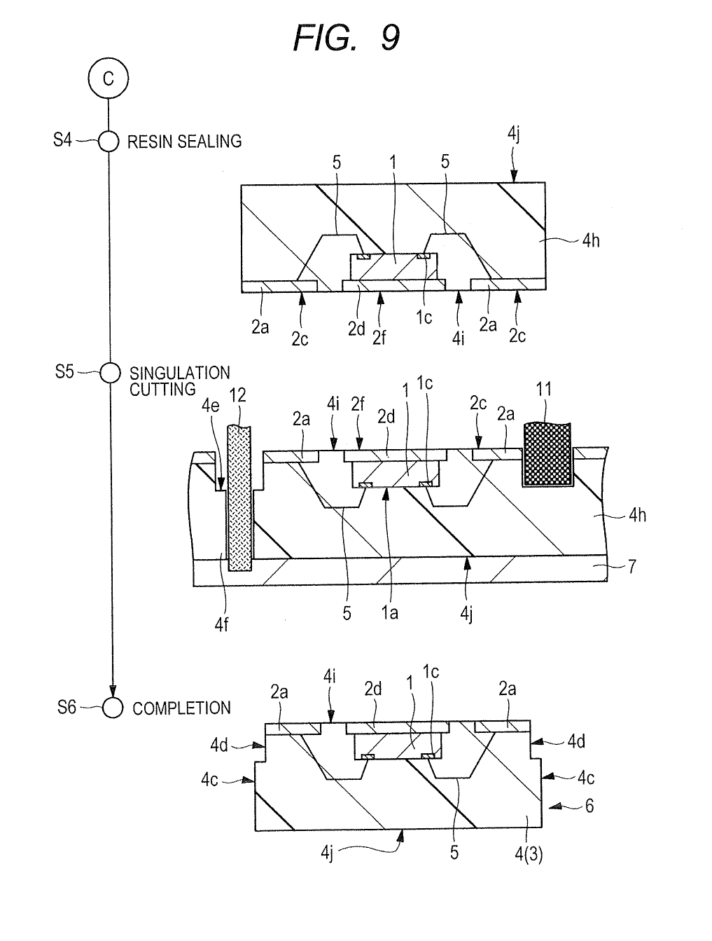

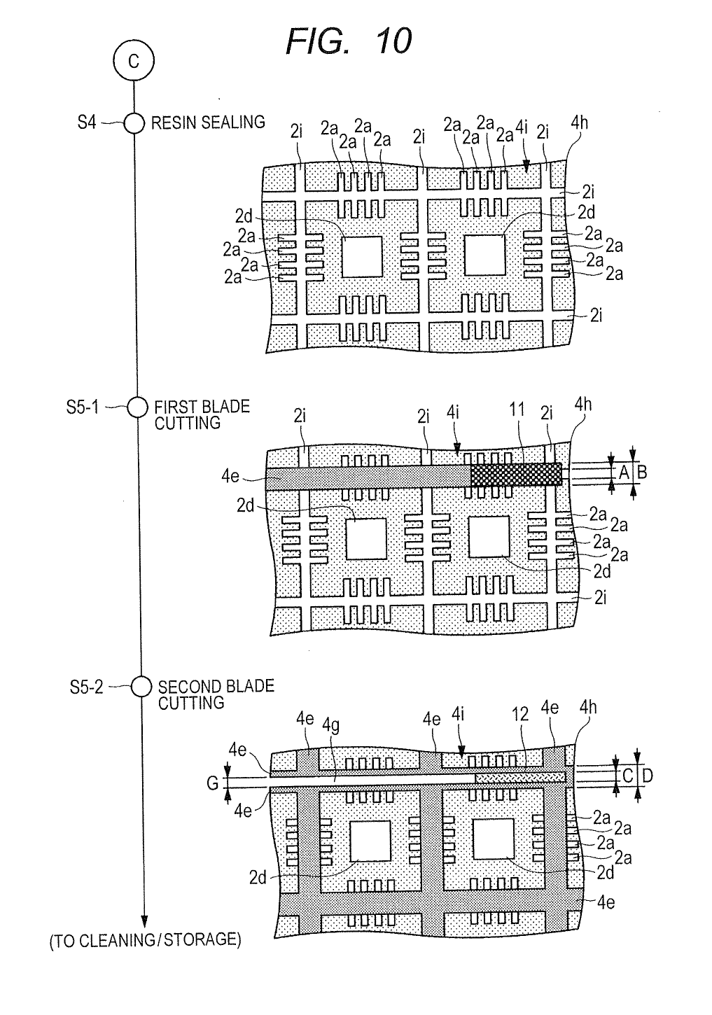

FIG. 6 comprises plan views showing the steps up to wire bonding in the assembly sequence of the semiconductor device shown in FIG. 1, FIG. 7 comprises sectional views showing the steps up to wire bonding in the assembly sequence shown in FIG. 6, FIG. 8 comprises plan views and a perspective view showing the steps of resin sealing to assembly completion in the assembly sequence of the semiconductor device in FIG. 1, FIG. 9 comprises sectional views showing the steps up to assembly completion in the assembly sequence shown in FIG. 8, and FIG. 10 comprises plan views showing the details of singulation cutting in the assembly sequence shown in FIG. 8.

A QFN 6 according to the present embodiment is assembled by adopting an MAP method. Firstly, as shown in frame loading at Step S1 of FIGS. 6 and 7, a lead frame 2 of a thin plate having a plurality of device regions 2j that are semiconductor device forming regions aligned in a matrix shape is prepared and loaded in an assembly line of a QFN 6.

Here, the device regions 2j are isolated from each other by tie bars 2i and each of the device regions 2j has a die pad 2d arranged in the vicinity of the center thereof, a plurality of leads 2a arranged around the die pad 2d, and four suspension leads 2g to support the die pad 2d at the corner parts thereof.

Further, each of the four suspension leads 2g branches into two branches in the vicinity of the tip on the side opposite to the die pad 2d and the branches are coupled to tie bars 2i. Furthermore, each of the suspension leads 2g is formed thin by applying half etching processing to the bottom face and a bottom face 2h is formed as shown in FIG. 5. The thickness of a suspension lead 2g is about a half of the thickness of a die pad 2d.

Furthermore, the plural leads 2a are supported by the tie bars 2i (coupled to the tie bars 2i).

Here, the lead frame 2 is a metal frame including an iron-nickel alloy or a copper alloy for example.

Successively, die bonding shown at Step S2 is carried out. That is, a semiconductor chip 1 is mounted over each of the top faces 2e of the plural die pads 2d in the lead frame 2 through a die bond material not shown in the figure as shown at Step S2 of FIG. 7.

Successively, wire bonding shown at Step S3 of FIGS. 6 and 7 is carried out. In the present wire bonding step, plural electrode pads 1c arranged over each of the obverse surfaces 1a of the plural semiconductor chips 1 are electrically coupled to plural leads 2a through metal wires 5 respectively. In this way, a semiconductor chip 1 is electrically coupled to leads 2a through metal wires 5.

Here, the plural metal wires 5 are gold wires, copper wires, aluminum wires, or the like.

Successively, resin sealing (molding) shown at Step S4 of FIGS. 8 and 9 is carried out. That is, plural semiconductor chips 1 are collectively sealed with a sealing body 4h.

Further, the sealing is carried out so as to expose the bottom face 2f of a die pad 2d from the bottom face 4i of the sealing body 4h as shown in FIG. 9.

Furthermore, as shown in FIG. 5, the bottom face of each of the suspension leads 2g is formed so as to be thin by half etching processing and hence resin sealing is applied so that a resin may come around on the side of the bottom faces 2h of the suspension leads 2g and the bottom faces 2h of the suspension leads 2g may be covered with the sealing body 4h (4).

By so doing, after the collective sealing, as shown at Step S4 of FIG. 10, die pads 2d (the bottom faces 2f of die pads 2d), plural leads 2a (the bottom faces 2c of plural leads 2a), and tie bars 2i are exposed on the side of the bottom face 4i of the sealing body 4h.

Successively, singulation cutting shown at Step S5 of FIGS. 8 and 9 is carried out. Here, singulation is carried out by cutting the sealing body 4h and the plural leads 2a.

The features of the present embodiment are the characteristics of blades used in a singulation cutting step and the method of using them. Consequently, a generation mechanism of cutting burrs formed in package dicing (blade dicing) is explained firstly.

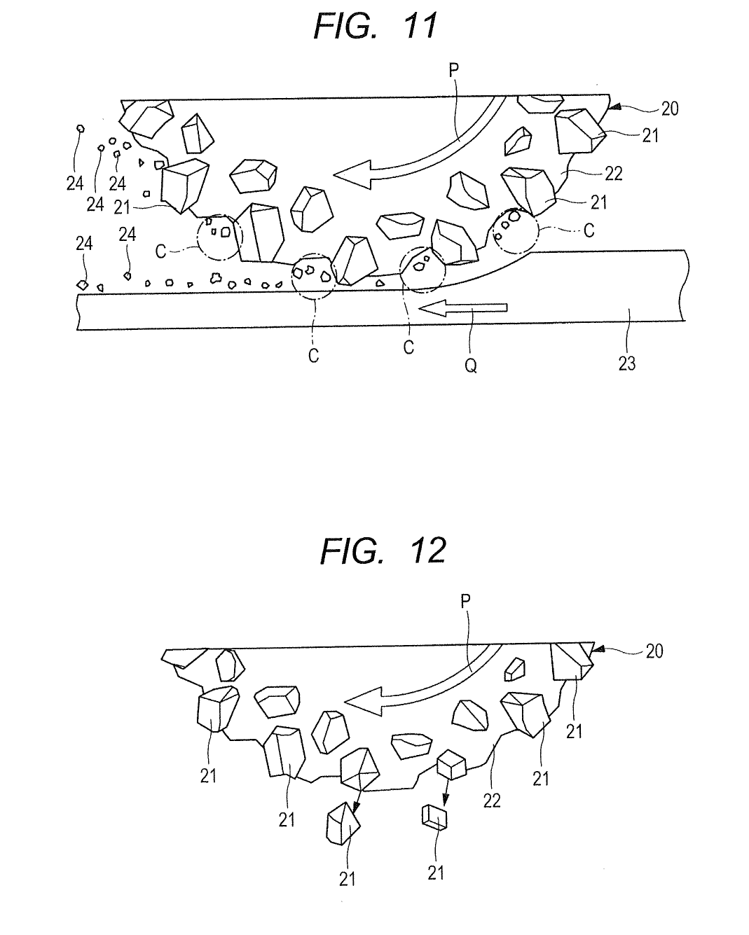

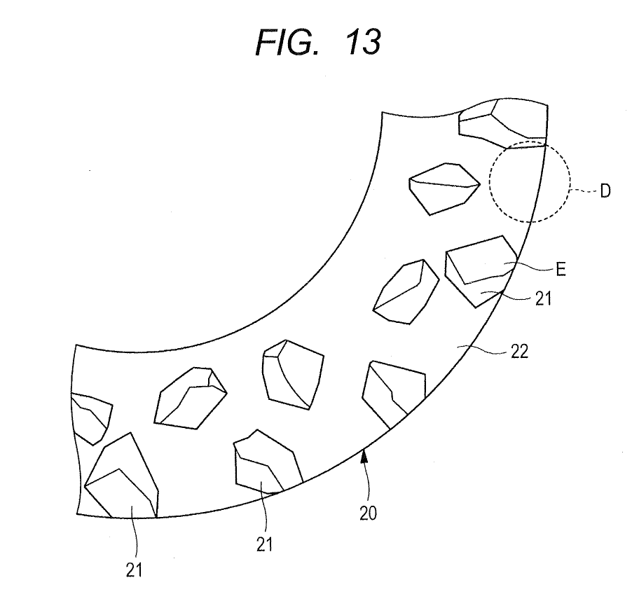

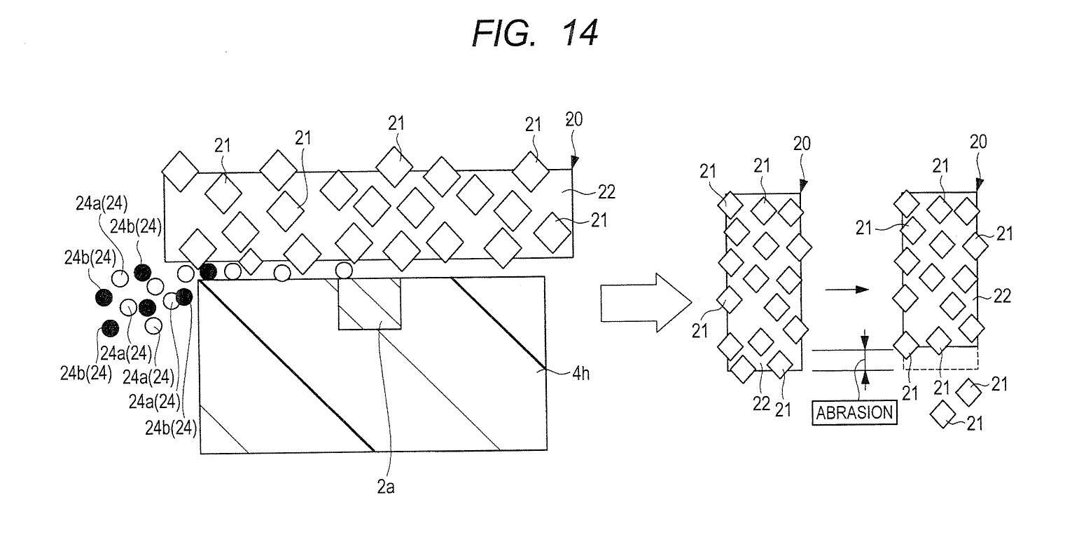

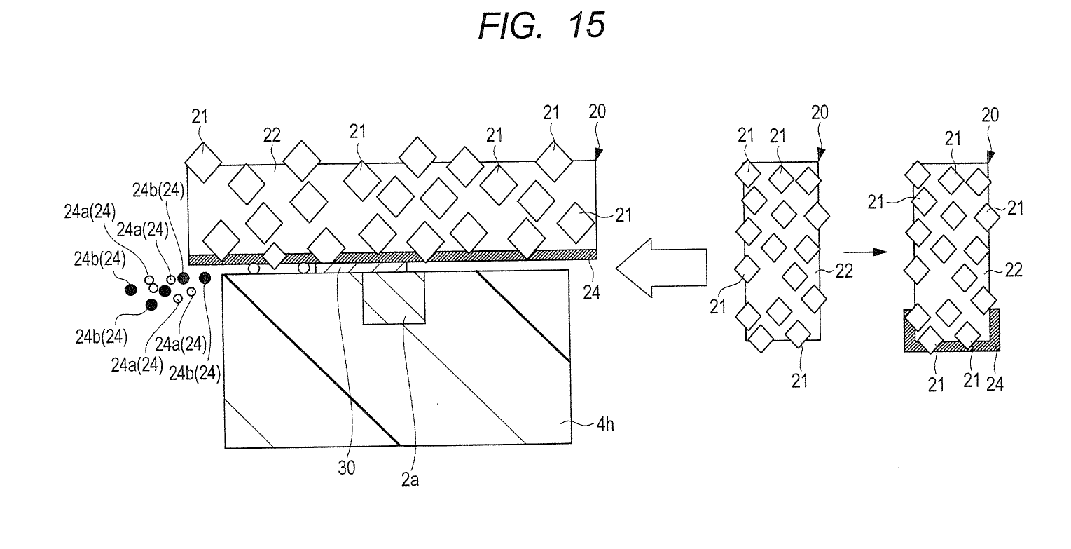

FIG. 11 is a conceptual diagram showing a cutting burr generating mechanism in package dicing, FIG. 12 is a conceptual diagram showing the cutting burr generating mechanism in FIG. 11, FIG. 13 is a conceptual diagram showing the cutting burr generating mechanism in FIG. 11, FIG. 14 comprises conceptual diagrams showing the state of a blade having no clogging in package dicing, and FIG. 15 comprises conceptual diagrams showing the state of a blade having clogging in package dicing.

As shown in FIG. 11, when a work 23 is cut with a blade 20, the cutting is carried out by the rotation (P) of the blade 20 and the progress (Q) of the work 23, the surface of the work 23 is shaved with abrasive grains 21 of the blade 20, and cutting chips (cutting powder) 24 of a binder 22 to retain the abrasive grains 21 and the work 23 are caused. On this occasion, the cutting chips 24 hang on cavities at C parts called chip pockets and are discharged in accordance with the rotation (P) of the blade 20.

When the cutting advances, as shown in FIG. 12, in the blade 20, old abrasive grains 21 fall off by the abrasion and cutting resistance of the binder 22 at the time of cutting, new abrasive grains 21 appear, and thereby sharpness is maintained.

FIG. 14 schematically shows an example of this case and represents a normal cutting state of a blade 20 having no clogging. That is, as shown in the cutting state of FIG. 14, a lead 2a (terminal) and a sealing body 4h (resin) are cut by asperities formed by abrasive grains 21 on the surface of the blade 20 in accordance with the rotation of the blade 20, cutting chips 24 such as metal chips 24a and resin chips 24b caused on the occasion are discharged, resultantly, as shown in the blade state (the drawing on the observers' right) of FIG. 14, old abrasive grains 21 fall off with the abrasion of the blade 20, new abrasive grains 21 are exposed, and sharpness is maintained.

As shown in FIG. 13 in contrast, in the case where the “retention force” of abrasive grains 21 that is a force to retain the abrasive grains 21 in a blade 20 is high (the case where a binder 22 is hard), old abrasive grains 21 hardly fall off. Further, the blade 20 itself hardly wears because the binder 22 is hard and hence aforementioned chip pockets are hardly formed (chip pockets are likely to be in the state of being crushed at the D part). As a result, clogging and jamming of the blade 20 are caused (the state where deteriorated abrasive grains 21 do not fall off continues at the E part) and asperities on the surface of the blade 20 decrease.

FIG. 15 schematically shows an example of this case and represents the situation of carrying out cutting in the state of a blade 20 having clogging. That is, as shown in the blade state (the drawing on the observers' right) of FIG. 15, if the retention force of abrasive grains 21 is high (hardly abrasive), the abrasive grains 21 hardly fall off, hence cutting chips 24 adhere to the surface of the blade 20, asperities of the surface decrease, and thereby the sharpness of the blade 20 deteriorates (in particular, metal chips 24a of a terminal or the like having a high ductility tend to adhere).

As a result, as shown in the cutting state (the drawing on the observers' left) of FIG. 15, since the asperities of the surface of the blade 20 decrease, the metal chips 24a of a lead 2a are not surely cut and elongated, and a cutting burr 30 is formed.

A cutting burr 30 is formed by the above mechanism.

Consequently, the characteristics of a blade 20 used in package dicing are a very important factor.

Manufacturing methods of an electroformed blade and a resin blade (metal blade) and the characteristics of those blades are explained hereunder.

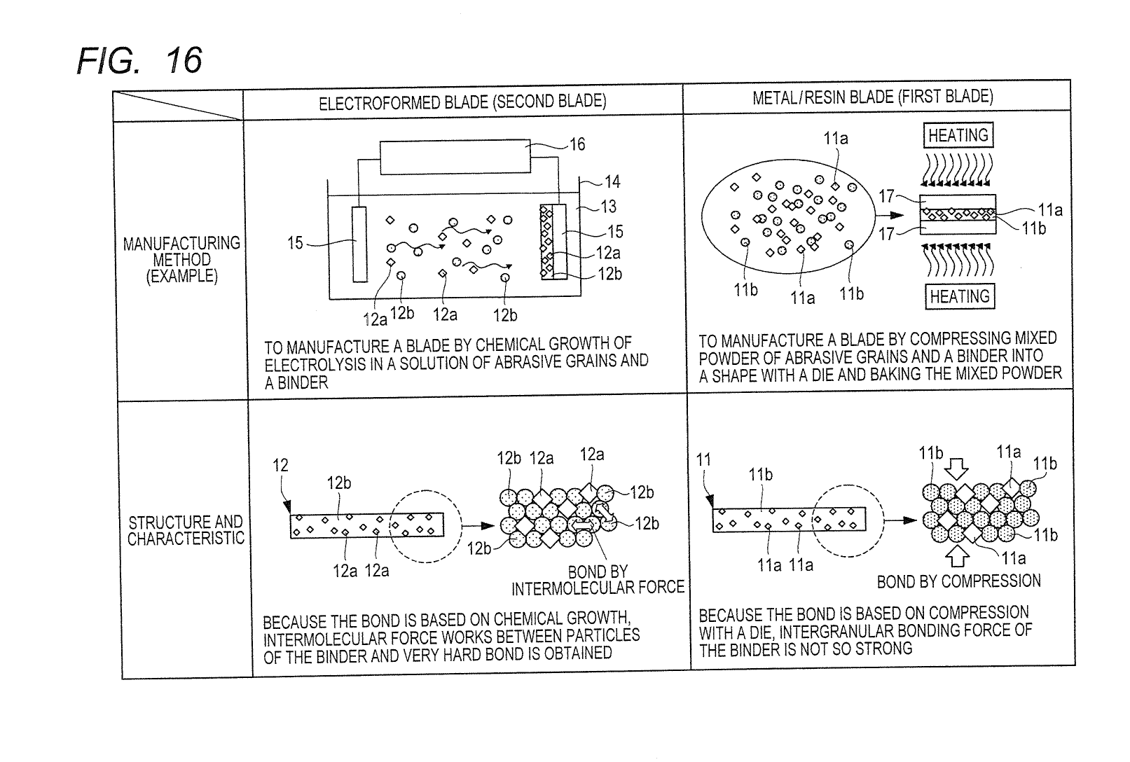

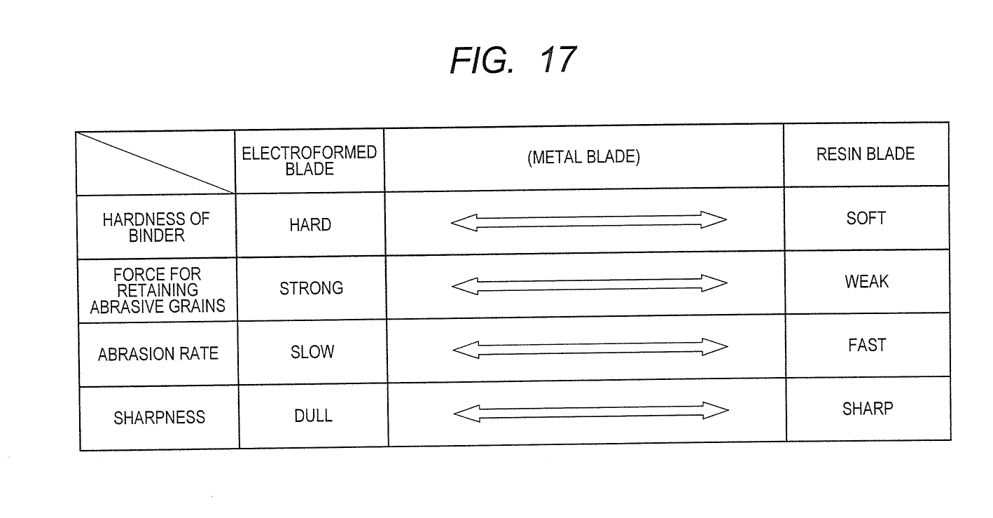

FIG. 16 comprises conceptual diagrams showing examples of the manufacturing methods of respective blades used in an embodiment according to the present invention and FIG. 17 is a conceptual diagram showing examples of the characteristics of the respective blades.

Firstly, a manufacturing method of a resin blade (first blade) 11 shown in FIG. 16 is explained. A resin blade 11 is manufactured by compressing mixed powder of abrasive grains 11a and a binder 11b into a shape with a die 17 and baking (sintering) the mixed powder. Consequently, since the bond is based on the compression with a die 17, an intergranular bonding force between the abrasive grains 11a and the binder 11b to retain the abrasive grains 11a is not so strong. In general, the force of a binder 11b for retaining abrasive grains 11a in a resin blade 11 is not so strong as (lower than) that of an electroformed blade that will be described later in many cases.

In this way, the characteristics of a resin blade 11 are that: the manufacturing is facilitated because of compression forming with a die 17 and baking and the manufacturing cost decrease because mass production is possible. Further, it is possible to keep sharpness because the wear of the blade main body is fast. Here, with regard to a metal blade too, the manufacturing method and characteristics thereof are similar to those of a resin blade 11.

Meanwhile, a manufacturing method of an electroformed blade (second blade) 12 shown in FIG. 16 is explained as follows. The manufacturing is carried out by installing two electrodes 15 (one is a seat) electrically coupled to a rectifier 16 in a solution 13 containing abrasive grains 12a and a binder 12b and being contained in a tank 14, applying electrolysis by feeding electric current in the state, and chemically growing the abrasive grains 12a and the binder 12b to retain the abrasive grains 12a over one electrode 15 acting as the seat. Consequently, because the bond is based on chemical growth, intermolecular force works between particles of the binder 12b, very hard bond is obtained, and a blade main body is formed hard. In general, the force of a binder 12b for retaining abrasive grains 12a in an electroformed blade 12 is strong (high) in comparison with that of the aforementioned resin blade (metal blade) in many cases.

In this way, a characteristic of an electroformed blade 12 is that the electroformed blade 12 is robust and hardly wears.

The manufacturing methods of a resin blade 11 and an electroformed blade 12 have been explained heretofore. Summary of the characteristics of an electroformed blade 12, a resin blade 11, and a metal blade is shown in FIG. 17.

One of the major characteristics is that, with regard to the hardness of the binders (11b and 12b), the binder of the electroformed blade 12 is harder than the binder of the resin blade 11. Further, with regard to the retention force of the abrasive grains (11a and 12a), the retention force of the electroformed blade 12 is stronger (higher) than the retention force of the resin blade 11. Furthermore, with regard to an abrasion rate, the abrasion rate of the electroformed blade 12 is lower than the abrasion rate of the resin blade 11. In addition, with regard to the sharpness of a blade main body, the sharpness of the electroformed blade 12 is duller than the sharpness of the resin blade 11.

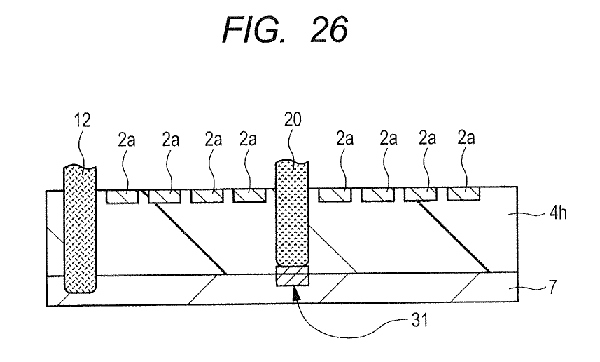

Consequently, a resin blade 11 of good sharpness has a characteristic of hardly forming such a cutting burr 30 as shown in FIG. 25 and hence is suitable for cutting a metal member or a resin member. In contrast, although an electroformed blade 12 having poor sharpness is likely to form a cutting burr 30, it has the characteristic of a low abrasion rate and hence such a remaining uncut part 31 as shown in FIG. 26 is hardly formed. Consequently, an electroformed blade 12 is suitable mainly for cutting a resin member.

In this way, performance required for a resin blade 11 other hand, performance required for an electroformed blade 12 is the prevention of clogging to a resin and wear resistance.

Here, a metal blade tends to have an intermediate characteristic between an electroformed blade 12 and a resin blade 11 in many cases.

Singulation cutting in the assembly of a QFN 6 is carried out by taking advantages of the characteristics of the above respective blades.

In a singulation cutting step for assembling a semiconductor device (QFN 6) according to the present embodiment, a structure after resin sealing, namely a member mainly including two kinds of materials such as leads 2a (metal) and a sealing body 4h (resin), has to be cut. On this occasion, in the structure of a QFN 6, leads 2a and suspension leads 2g that are metal members to be cut are arranged over the bottom face 4b of a sealing body 4 or at positions close to the bottom face 4b in the thickness direction as shown in FIGS. 1, 4, and 5.

Consequently, in a singulation cutting step for assembling a QFN 6 according to the present embodiment, firstly, a sealing body 4h around leads 2a and suspension leads 2g including the leads 2a and the suspension leads 2g is cut up to the middle of the sealing body 4h in the thickness direction (first cutting step). A resin blade (first blade) 11 is used for the cutting. Successively, only a part of resin being uncut with the resin blade 11 and remaining (the remaining uncut part 4f in FIG. 9) is cut with an electroformed blade 12 (second cutting step) and the cutting is completed.

That is, a prominent characteristic of a singulation cutting step according to the present embodiment is that: the cutting step is divided into two steps; different blades are used in accordance with the specific features of the steps; and thereby cutting burrs 30 in FIG. 25 and a remaining uncut part 31 in FIG. 26 are prevented from forming. In a QFN 6 according to the present embodiment, leads 2a and suspension leads 2g, which are metallic members, are arranged over the bottom face 4b of a sealing body 4 or positions closer to the bottom face 4b in the thickness direction as stated earlier. Then in the singulation cutting step, the bottom face 4i of a sealing body 4h after resin sealing is supported upward and cutting is carried out by inserting blades from above in the state as shown at Step S5 of FIG. 9. On the occasion, since blades are inserted from above, namely from the side of the bottom face 4i, as cutting of a first step, the sealing body 4h is cut up to a position near the center of the sealing body 4h in the thickness direction or up to a position short of the center with a resin blade (first blade) 11 and thus plural leads 2a and suspension leads 2g which are metallic members and the sealing body 4h around the leads are cut.

After finishing the cutting of the first step, the blade is switched from the resin blade 11 to an electroformed blade (second blade) 12 and the cutting of the second step is carried out with the electroformed blade 12. That is, in the cutting of the second step, a part of the sealing body 4h being uncut and remaining in the cutting of the first step (remaining uncut part 4f which is only a resin part) is cut with the electroformed blade 12 and the cutting (singulation cutting) is completed.

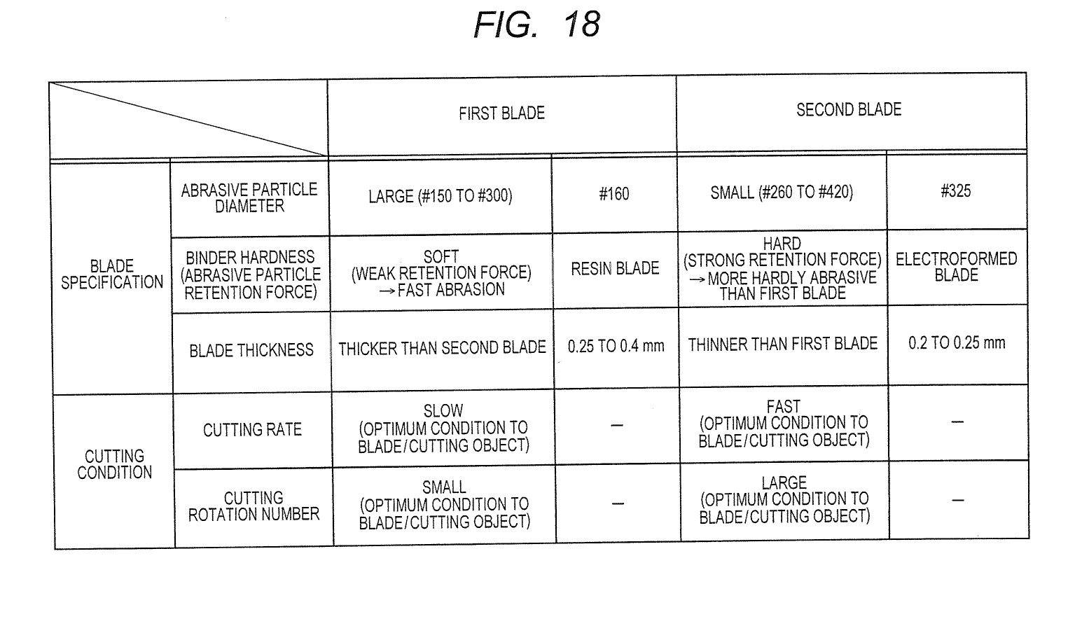

Here, the specifications and cutting conditions of a first blade and a second blade used in singulation cutting according to the present embodiment are explained in reference to FIG. 18. FIG. 18 is a conceptual diagram showing examples of the specifications and the cutting conditions of respective blades used in an embodiment according to the present invention.

As shown in the specifications of the blades in FIG. 18, the first blade (resin blade 11) used in cutting at the first step cuts metal such as leads 2a and suspension leads 2g together with resin and hence it is preferable that the sharpness of the first blade is high. In contrast, the second blade (electroformed blade 12) used in cutting at the second step cuts only a resin part (remaining uncut part 4f) that is uncut and remains at the first step and hence the sharpness may be low in comparison with the first blade at the first step.

Consequently, in order to improve the sharpness of a first blade, the abrasive grain diameter of the first blade is increased so as to be larger than the abrasive grain diameter of a second blade. For example, it is preferable to set the abrasive grain diameter of a first blade at about #150 to #300 and the abrasive grain diameter of a second blade at about #260 to #420.

An example of the combination of abrasive grain diameters is that the abrasive grain diameter of a first blade is #160 and the abrasive grain diameter of a second blade is #325.

Further, with regard to the hardness (force for retaining abrasive grains) of a binder in the specifications of the blades shown in FIG. 18, in cutting at the first step, a blade having a weak (low or small) abrasive grain retention force is used in order to inhibit a cutting burr 30 of metal from forming during cutting. That is, a blade containing a binder of a low hardness, namely having a high abrasion rate, is used.

On the other hand, in cutting at the second step, since a resin part is cut and such a remaining uncut part 31 as shown in FIG. 26 must be prevented from forming, a blade having a low abrasion rate is used. That is, a blade containing a binder of a high hardness and having a strong (high or large) abrasive grain retention force is used.

Consequently, the force of a first blade used in cutting at the first step for retaining abrasive grains is lower than the force of a second blade used in cutting at the second step for retaining abrasive grains. That is, preferably a resin blade 11 is used as the first blade and an electroformed blade 12 is used as the second blade.

In other words, the abrasion rate of a first blade (resin blade 11) used in cutting at the first step is higher than the abrasion rate of a second blade (electroformed blade 12) used in cutting at the second step.

As a result, in cutting at the first step, by using a resin blade 11, in comparison with an electroformed blade 12, the retention force of abrasive grains 11a is weak, the wear of the blade is fast, hence sharpness increases, and a cutting burr 30 of metal can be inhibited from forming. On the other hand, in cutting at the second step, by using an electroformed blade 12, in comparison with a resin blade 11, the retention force of abrasive grains 12a is strong, the blade hardly wears, and hence a remaining uncut part 31 of a sealing body 4h can be inhibited from forming.

Further, with regard to a blade thickness in the specifications of the blades shown in FIG. 18, the thickness of a second blade (electroformed blade 12) used in cutting at the second step is set so as to be thinner than the thickness of a first blade (resin blade 11) used in cutting at the first step.

In this way, as shown in the singulation cutting at Step 5 of FIG. 9, when cutting is carried out with an electroformed blade 12 in cutting at the second step, it is possible to: prevent the electroformed blade 12 from touching the cut planes 2k of leads 2a and the cut planes 2m of suspension leads 2g, which are exposed on a second side face 4d formed by cutting at the first step and shown in FIG. 1; and inhibit a cutting burr 30 from forming.

For example, the thickness of a first blade (resin blade 11) is about 0.25 to 0.4 mm and the thickness of a second blade (electroformed blade 12) is about 0.2 to 0.25 mm. It is preferable to select blade thicknesses so that the thickness of a resin blade 11 may be thicker than the thickness of an electroformed blade 12 in the aforementioned thickness ranges.

Cutting conditions of the blades shown in FIG. 18 are explained hereunder. Since metal is cut also at the first step, cutting resistance is large in comparison with cutting only resin at the second step. Consequently, as cutting conditions, it is preferable that the operations (a feed speed and a rotation number) on the blade side in cutting at the first step are set so as to lower the cutting resistance in cutting at the first step and inhibit a cutting burr 30 from forming.

Consequently, the feed speed of a second blade (electroformed blade 12) used in cutting at the second step is set so as to be faster than the feed speed of a first blade (resin blade 11) used in cutting at the first step. In other words, by setting the feed speed of a first blade (resin blade 11) so as to be slower than the feed speed of a second blade (electroformed blade 12), it is possible to: lower cutting resistance in cutting at the first step; and inhibit a cutting burr 30 caused by dragging of metal from forming.

Further, by setting the feed speed of a second blade (electroformed blade 12) so as to be faster than the feed speed of a first blade (resin blade 11), it is possible to improve throughput in the cutting of only resin at the second step.

As the cutting conditions of blades further, it is preferable to set the cutting rotation number of a second blade (electroformed blade 12) so as to be larger than the cutting rotation number of a first blade (resin blade 11). In the same way as a feed speed stated above, by setting the cutting rotation number of a first blade (resin blade 11) so as to be smaller than the cutting rotation number of a second blade (electroformed blade 12), it is possible to: lower cutting resistance in cutting at the first step; and inhibit a cutting burr 30 caused by metal from forming.

Likewise, by setting the cutting rotation number of a second blade (electroformed blade 12) so as to be larger than the cutting rotation number of a first blade (resin blade 11), it is possible to improve throughput in the cutting of only resin at the second step.

Specific examples of singulation cutting steps with a resin blade 11 and an electroformed blade 12 according to the present embodiment are explained hereunder.

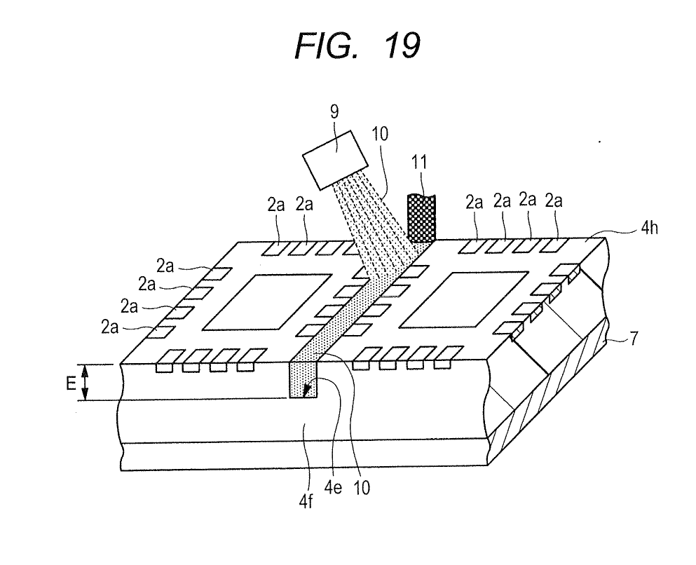

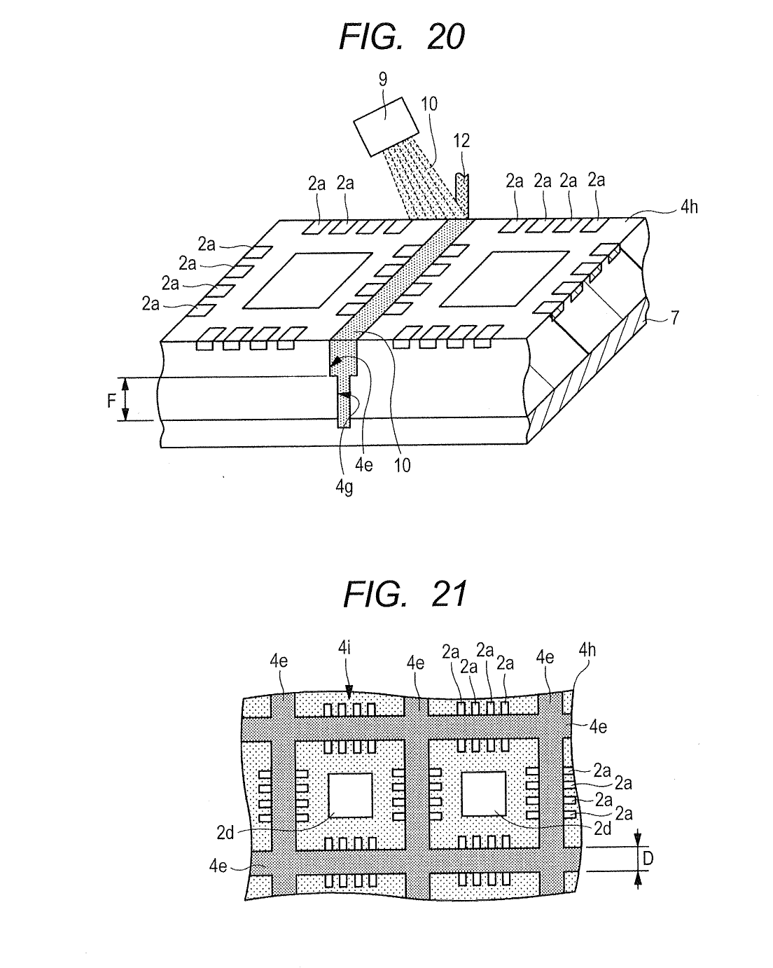

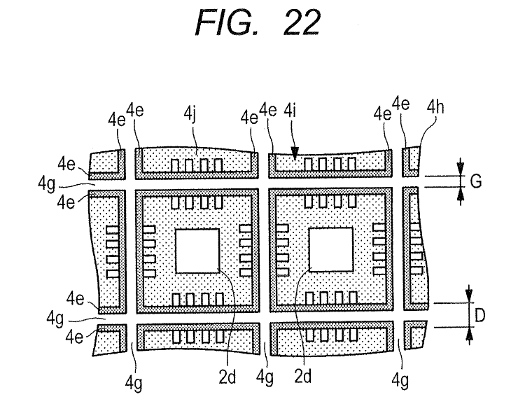

FIG. 19 is a perspective view showing an example of the state of cutting with a first blade (resin blade 11) in a singulation cutting step according to an embodiment of the present invention, FIG. 20 is a perspective view showing an example of the state of cutting with a second blade (electroformed blade 12) in a singulation cutting step according to an embodiment of the present invention, FIG. 21 is a plan view showing an example of the structure after cut with the first blade in FIG. 19, and FIG. 22 is a plan view showing an example of the structure after cut with the second blade in FIG. 20.

Firstly, cutting at the first step in a singulation cutting step according to an embodiment is explained. As stated above, a resin blade 11 (first blade) is used in cutting at the first step.

In a singulation cutting step, as shown at Step S5 of FIG. 9, cutting is carried out by supporting a sealing body 4h by attaching the top face 4j of the sealing body 4h to a dicing tape 7 and inserting a first blade and a second blade from the side of the bottom face 4i (upper side) of the sealing body 4h in the state of directing the bottom face 4i of the sealing body 4h upward. Meanwhile, although an example of fixedly supporting a sealing body 4h with a dicing tape 7 is described here, the present invention is not limited to the example. The present invention can be applied similarly to the case of a jig dicing method (method of adsorbing and fixing a sealing body 4h over a stage jig).

On the occasion, in first blade cutting (cutting at a first step) shown at Step S5-1 of FIG. 10, as shown at Step S5 of FIG. 9, firstly a resin blade 11 is inserted from the side of the bottom face 4i of the sealing body 4h in the state of supporting the top face 4j of the sealing body 4h with the dicing tape 7, plural leads 2a and tie bars 2i shown in FIG. 10 are cut, and a part of the sealing body 4h is cut. That is, a resin blade 11 is inserted from the side of the bottom face 4i of the sealing body 4h and plural leads 2a and tie bars 2i are cut into pieces. On this occasion, the width of a tie bar 2i is narrower than the width of the resin blade 11. In other words, as shown at Step S5-1 of FIG. 10, the first blade cutting is carried out by using a resin blade 11 having a width B wider than the width A of a tie bar 2i (A<B).

As an example, the width of a tie bar 2i is about 0.15 mm and the width of a resin blade 11 is about 0.25 to 0.4 mm.

By setting the width of a resin blade 11 so as to be wider than the width of a tie bar 2i in this way, it is possible to cut off the tie bar 2i unfailingly as shown in FIG. 21.

Further, in first blade cutting with a resin blade 11 and second blade cutting with an electroformed blade 12 after the first blade cutting, the thickness of a sealing body 4h cut with the electroformed blade 12 is set so as to be identical to or thicker than the thickness of the sealing body 4h cut with the resin blade 11.

In other words, the thickness E of a sealing body 4h to be cut with a resin blade 11 shown in FIG. 19 is identical to or thinner than the thickness F of the sealing body 4h to be cut with an electroformed blade 12 shown in FIG. 20. That is, cutting resistance is high because a tie bar 2i including metal is cut with a first blade and hence it is preferable that the cutting is carried out up to a depth slightly deeper than the thickness of the tie bar 2i and a remaining uncut part 4f shown in FIG. 19 having a relatively thick thickness is cut with an electroformed blade 12 in second blade cutting.

Here, in a cutting step shown in FIG. 19, cutting is carried out while water 10 is splayed from a nozzle 9 toward a resin blade 11 and a cutting position. In this way, cutting resistance decreases and cutting chips can be discharged. This will be explained hereunder in detail.

By carrying out first blade cutting, a first groove 4e of a width D is formed in a sealing body 4h as shown at Step S5 of FIG. 8 and in FIGS. 19 and 21 and further the water 10 splayed at the time enters the first groove 4e and is in the state of being accumulated as shown in FIG. 19.

Successively, second blade cutting (second step cutting) shown in FIGS. 10 and 20 is carried out in the state of accumulating the water 10 in the first groove 4e. That is, second blade cutting with an electroformed blade 12 is carried out in the state of accumulating the water 10 splayed to a resin blade 11 and the cutting position during cutting in a first blade cutting step in the first groove 4e shown in FIG. 19.

In this way, the water 10 accumulated in the first groove 4e acts as lubricating water and hence it is possible to decrease the friction resistance (cutting resistance) between the electroformed blade 12 and resin. In this way, it is possible to decrease “burn” caused by friction heat between the electroformed blade 12 and resin. Here, in second blade cutting, an electroformed blade 12 having a thickness thinner than the thickness of a resin blade 11 is inserted into a first groove 4e and a remaining uncut part 4f including only a sealing body 4h is cut.

In other words, a second groove 4g of a width G is formed by cutting a remaining uncut part 4f in FIG. 19 with an electroformed blade 12 having a width C narrower than the width D of the first groove 4e (C<D) as shown in the second blade cutting at Step S5-2 of FIG. 10.

In this way, it is possible to inhibit an electroformed blade 12 from touching the cut planes 2k of leads 2a and the cut planes 2m of suspension leads 2g formed by first blade cutting and inhibit cutting burrs 30 from forming.

Here, in a second blade cutting step too, cutting is carried out while water 10 is splayed from a nozzle 9 toward an electroformed blade 12 and the cutting position as shown in FIG. 20. In this way, it is possible to decrease friction resistance (cutting resistance) between the electroformed blade 12 and resin and discharge cutting chips.

Further, in cutting with an electroformed blade 12, cutting is carried out until the electroformed blade 12 reaches a dicing tape 7 as shown in FIG. 20. In this way, a second groove 4g having a width G narrower than the width D of a first groove 4e is formed as shown at Step S5 of FIG. 8 and in FIGS. 20 and 22.

Furthermore, since only resin is cut with an electroformed blade 12, the thickness of a sealing body 4h cut with the electroformed blade 12 is identical to or thicker than the thickness of the sealing body 4h cut with a resin blade 11. Consequently, the depth of a second groove 4g formed by cutting with the electroformed blade 12 is identical to or deeper than the depth of a first groove 4e.

Importance of carrying out second blade cutting in the state of accumulating water 10 in a first groove 4e formed in first blade cutting is explained hereunder.

In the present embodiment, the thickness of a sealing body 4h cut in second blade cutting is thicker than the thickness of the sealing body 4h cut in first blade cutting as stated above. Consequently, in consideration of friction heat caused by friction resistance at cutting, to carryout second blade cutting in the state of accumulating water 10 in a first groove 4e formed in first blade cutting is very effective in securing the quality of a semiconductor device.

It can be said that this is largely different in meaning from step dicing in conventional wafer (Si) dicing.

Usually a wafer is diced through a back grind step. A wafer thickness at the time is usually about 400 μm (0.4 mm) or less. In contrast, the thickness of a package cut in package dicing is about 1,000 μm (1.0 mm) and more than twice. Consequently, the quantity of cutting chips is overwhelmingly large in comparison with the case of dicing a wafer. If cutting chips are not discharged orderly, cutting is carried out in the state of involving the cutting chips, hence a cut plane gets rough by the cutting chips, and the quality of a semiconductor device is affected. Further, that the thickness of a cut part is thick means that a plane touching a blade is also large (broad) and “burn” of a resin cut plane caused by friction heat generated between a blade and resin cannot be ignored. Furthermore, if the thickness of a cut part is thick, cutting water hardly reaches around up to a point (lower back) where a blade touches resin and hence friction heat further increases. Consequently, the feature of carrying out second blade cutting in the state of accumulating water 10 in a first groove 4e as stated above is an important point for improving the outer shape accuracy of a semiconductor device and securing the quality of a cut plane in package dicing.

In addition, the major characteristics heretofore explained in the present embodiment are particularly effective in preventing a remaining uncut part from being formed when a sealing body 4h is fixedly supported with a dicing tape 7.

The thickness of a dicing tape 7 is usually about 100 μm in many cases. In second blade cutting, the depth of cutting is set so that the cutting may reach the dicing tape 7 as stated above but, if the dicing tape 7 is completely cut, a singulated QFN 6 cannot be retained, and hence the cutting depth has to be within the thickness of the dicing tape 7 (namely within 100 μm). That is, the part of a blade breaking through a QFN 6 is less than 100 μm. If a second blade is a blade of a high abrasion rate in the same manner as a resin blade 11, the blade does not break through the QFN 6 when friction advances and a remaining uncut part 31 is formed instantly. Consequently, the characteristic of using an electroformed blade 12 having a low friction as a second blade has an advantage for preventing a remaining uncut part from forming.

Second blade cutting at Step S5-2 of FIG. 10 is finished as stated above.

Successively, cleaning and storage are carried out and the assembly of a QFN 6 shown at Step S6 of FIG. 8 and Step S6 of FIG. 9 is completed.

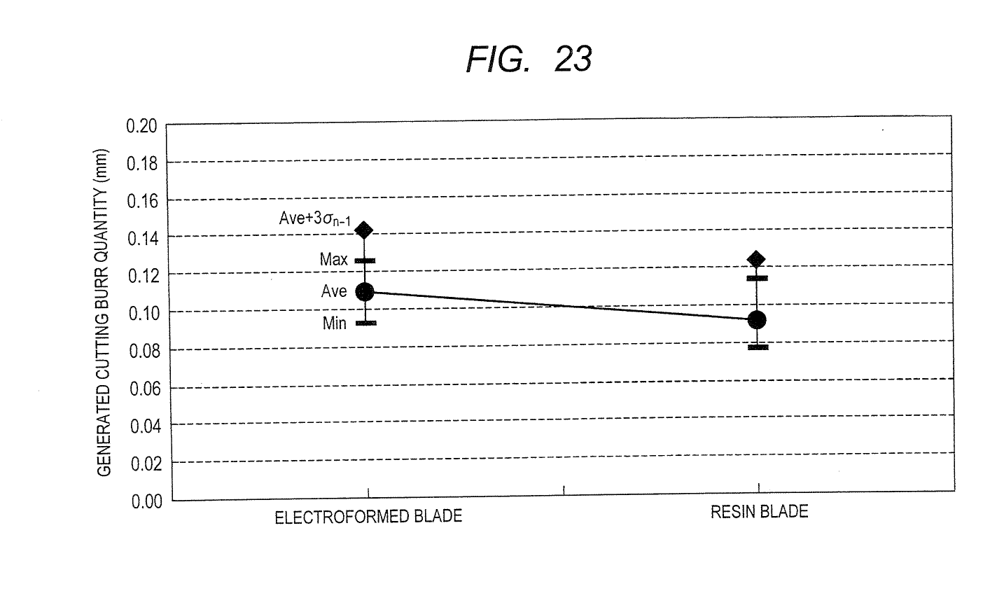

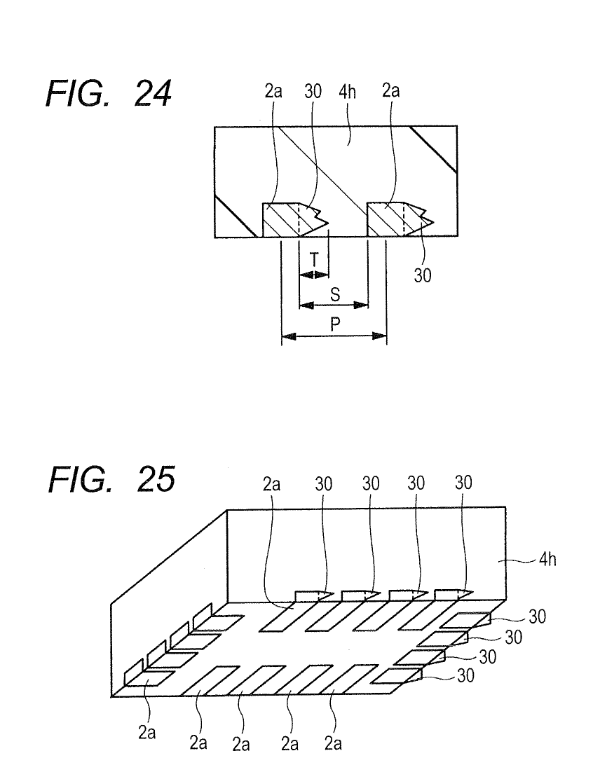

The evaluation results of the quantities T of generated cutting burrs in the cases of an electroformed blade 12 and a resin blade 11 are explained hereunder in reference to FIGS. 23 and 24.

FIG. 23 is a graph comparing the quantities T of the generated cutting burrs measured in the cases of an electroformed blade and a resin blade and FIG. 24 is a conceptual diagram showing cutting burrs in the measurement of FIG. 23.

Here, the evaluation data shown in FIG. 23 are obtained from the blades after the cutting of about 500 m in both the cases of an electroformed blade 12 and a resin blade 11.

Further in a QFN 6, the gap S between leads 2a is 0.38 mm when the pitch P between the leads 2a shown in FIG. 24 is 0.5 mm and the gap S between leads 2a is 0.28 mm when the pitch P between the leads 2a is 0.4 mm.

Consequently, in order not to generate short circuit between leads 2a caused by cutting burrs 30, it is desirable to control the cutting burrs 30 so as to be a half of the gap S between the leads 2a also in consideration of the margin of mass production.

As shown in FIG. 23, when cutting is carried out with an electroformed blade 12, the quantities T of the generated cutting burrs exceed 0.14 mm in terms of 3σ and hence they exceed the upper limit with a QFN 6 having a pitch P between leads 2a of 0.4 mm.

Consequently, it is understood that, in singulation cutting carried out at two steps according to the present embodiment, in first blade cutting (first step cutting) accompanying metal cutting (tie bars 2i and leads 2a), it is appropriate to use a resin blade 11.

In other words, a major characteristic of the present embodiment that has heretofore been explained is that it is a technology effective in preventing short circuit between adjacent leads caused by a cutting burr (electrically conductive burr) when a pitch between leads is narrowed (pitch narrowing) in the trends of the increase in the number of pins and the downsizing of a semiconductor device.

By a manufacturing method of a semiconductor device according to the present embodiment, it is possible to inhibit cutting burrs 30 from forming at metal parts shown in FIG. 25 by cutting the metal parts including tie bars 2i and leads 2a and a part of a sealing body 4h with a soft resin blade (first blade) 11 as first step cutting (first blade cutting) at the time of package dicing (singulation cutting).

Successively, by cutting a resin part that is a remaining uncut part 4f being uncut and remaining at a first step with a hard electroformed blade 12 as second step cutting (second blade cutting), it is possible to decrease the occurrence of a remaining uncut part 31 shown in FIG. 26 because the progression of the abrasion in the blade main body is slow.

In this way, it is possible to improve the reliability of a QFN (semiconductor device) 6.

Although the invention established by the present inventors has heretofore been explained concretely on the basis of the embodiment according to the invention, it goes without saying that the present invention is not limited to the embodiment according to the invention and can be variously modified within the range not deviating from the tenor thereof.

For example, although explanations have been made by taking a QFN 6 as an example of a semiconductor device in the above embodiment, any semiconductor device other than a QFN may be adopted as long as it is a semiconductor device that uses a lead frame in the assembly and is subjected to package dicing (singulation cutting) with a blade after resin sealing of an MAP method is applied.

What is claimed is:

1. A method for manufacturing a semiconductor device, comprising the steps of:
(a) preparing a lead frame having a plurality of chip mounting parts and a plurality of leads arranged around said respective plural chip mounting parts;
(b) mounting a plurality of semiconductor chips over the top faces of said respective plural chip mounting parts;
(c) electrically coupling a plurality of pads arranged over the surfaces of said respective plural semiconductor chips to said plural leads;
(d) collectively sealing said plural semiconductor chips with a sealing body; and
(e) cutting and singulating said sealing body and said plural leads,
wherein the bottom faces of said respective plural leads are exposed from the bottom face of said sealing body in said step (d),
wherein said step (e) further includes the steps of:
(e1) retaining the top face of said sealing body;
(e2) cutting a part of said sealing body and said plural leads from the bottom face side of said sealing body with a first blade; and
(e3) inserting a second blade having a thickness thinner than the thickness of said first blade into a first groove formed in said step (e2) and cutting the remaining uncut part of said sealing body, and
wherein the force of said first blade for retaining abrasive grains is lower than the force, of said second blade for retaining abrasive grains.

2. A method for manufacturing a semiconductor device according to claim 1, wherein said step (e3) is carried out in the state of accumulating water in said first groove.

3. A method for manufacturing a semiconductor device according to claim 2, wherein only said sealing body is cut in said step (e3).

4. A method for manufacturing a semiconductor device according to claim 3,
wherein said lead frame further has tie bars to which said plural leads are coupled;
wherein said step (e2) is a step of cutting and separating said plural leads from said tie bars, and
wherein the width of said tie bars is narrower than the width of said first blade.

5. A method for manufacturing a semiconductor device according to claim 1, where said steps (e2) and (e3) are carried out so that the thickness of said sealing body cut with said second blade may be identical to or larger than the thickness of said sealing body cut with said first blade.

6. A method for manufacturing a semiconductor device according to claim 1,
wherein said abrasive grains of said first blade and a binder to retain said abrasive grains are bound to each other by sintering, and
wherein said abrasive grains of said second blade and a binder to retain said abrasive grains are bound to each other by intermolecular force.

7. A method for manufacturing a semiconductor device according to claim 6, wherein said first blade is a resin blade and said second blade is an electroformed blade.

8. A method for manufacturing a semiconductor device according to claim 1, wherein said step (e1) is carried out by attaching the top face of said sealing body to a dicing tape.

9. A method for manufacturing a semiconductor device according to claim 1, wherein the diameters of said abrasive grains of said first blade are larger than the diameters of said abrasive grains of said second blade.

10. A method for manufacturing a semiconductor device according to claim 1, wherein the feed speed of said second blade is faster than the feed speed of said first blade.

11. A method for manufacturing a semiconductor device according to claim 1, wherein the rotation number of said second blade is larger than the rotation number of said first blade.

12. A method for manufacturing a semiconductor device according to claim 1, wherein said plural pads and said plural leads of said semiconductor chips are electrically coupled to each other with metal wires in said step (c).

13. A method for manufacturing a semiconductor device according to claim 12, wherein said plural metal wires are gold wires, copper wires, or aluminum wires.

14. A method for manufacturing a semiconductor device according to claim 1, wherein said step (d) is carried out so as to expose the bottom faces of said chip mounting parts from the bottom face of said sealing body.

15. A method for manufacturing a semiconductor device according to claim 14,
wherein said lead frame has suspension leads to support said chip mounting parts;
the bottom faces of said suspension leads are half-etched, and
said step (d) is carried out so as to cover the bottom faces of said suspension leads with said sealing body.

16. A method for manufacturing a semiconductor device according to claim 2, wherein said water accumulated in said first groove is water sprayed to said first blade at the time of cutting with said first blade in said step (e2).

17. A method for manufacturing a semiconductor device according to claim 2, wherein the depth of a second groove formed in cutting with said second blade is identical to or deeper than the depth of said first groove.

18. A method for manufacturing a semiconductor device according to claim 8, wherein cutting is applied until said second blade reaches said dicing tape in cutting with said second blade.

19. A method for manufacturing a semiconductor device, comprising the steps of:
(a) preparing a lead frame having a plurality of chip mounting parts and a plurality of leads arranged around said respective plural chip mounting parts;
(b) mounting a plurality of semiconductor chips over the top faces of said respective plural chip mounting parts;
(c) electrically coupling a plurality of pads arranged over the surfaces of said respective plural semiconductor chips to said plural leads;
(d) collectively sealing said plural semiconductor chips with a sealing body, and
(e) cutting and singulating said sealing body and said plural leads,
wherein the bottom faces of said respective plural leads are exposed from the bottom face of said sealing body in said step (d),
wherein said step (e) further includes the steps of:
(e1) retaining the top face of said sealing body;
(e2) cutting a part of said sealing body and said plural leads from the bottom face side of said sealing body with a first blade; and
(e3) inserting a second blade having a thickness thinner than the thickness of said first blade into a first groove formed in said step (e2) and cutting the remaining uncut part of said sealing body, and
wherein the abrasion rate of said first blade is larger than the abrasion rate of said second blade.
